(19) United States
(12) Patent Application Publication
(10) Pub. No.: US 2025/0290993 A1
(43) Pub. Date: Sep. 18, 2025

(54) DEVICE FOR ESTIMATING TWO STATES OF CHARGE OF A BATTERY, AND ASSOCIATED SYSTEM, AIRCRAFT AND METHOD

(71) Applicant: SAFRAN ELECTRICAL & POWER, BLAGNAC (FR)

(72) Inventors: Guillaume CHEROUVRIER, MOISSY-CRAMAYEL (FR); Guillaume PERCHERON, MOISSY-CRAMAYEL (FR); Alexis RENOTTE, MOISSY-CRAMAYEL (FR)

(73) Assignee: SAFRAN ELECTRICAL & POWER, BLAGNAC (FR)

(21) Appl. No.: 18/860,114

(22) PCT Filed: Apr. 6, 2023
(86) PCT No.: PCT/FR2023/050497

§ 371 Date: Oct. 25, 2024

(30) Foreign Application Priority Data
Apr. 25, 2022 (FR) 2203824

(51) Int. Cl. G01R 31/387; G01R 31/367; G01R 31/371; G01R 31/374; G01R 31/396; H01M 10/48

(52) U.S. Cl. CPC G01R 31/387; G01R 31/367; G01R 31/374; G01R 31/396; H01M 10/482; H01M 10/486; G01R 31/371; H01M 2220/20

(57) ABSTRACT

A device estimates two states of charge (SOC1, SCO2) of a battery that has a plurality of cells connected to one another, at least a fraction of the plurality of cells forming at least one set of cells having at least two cells. The device includes first determining means that are configured to determine a first state of charge (SOC1) of the battery from the voltage across the terminals of each cell and the temperature in the vicinity of each cell, and the current flowing through the terminals of the plurality of cells. The device further includes second determining means configured to determine a second state of charge (SCO2) of the battery from at least one variable measured across the terminals of the set of cells.

### TECHNICAL FIELD OF THE INVENTION

The invention relates to estimating states of charge of batteries, and more specifically devices for estimating two states of charge of a battery.

The invention also relates to a power supply system for an aircraft comprising such a device, an aircraft comprising such a system, and a method for redundant estimation of two states of charge of a battery.

### PRIOR ART

Generally speaking, aircraft are propelled by turbine engines of the turboprop, turbojet or turbine type.

However, the use of turbine engines is associated with significant noise emissions and high fossil fuel consumption, particularly of kerosene, also generating significant polluting emissions.

In order to reduce the noise and polluting emissions, aircraft propulsion may be electric or hybrid, by replacing all or part of the turbine engines intended to produce the thrust of the aircraft with electric motors.

The electric motors are powered by propulsion batteries.

In order to guarantee the flight safety of an aircraft fitted with an electric or hybrid propulsion system, the state of charge SOC of each propulsion battery must be determined, defined as being the ratio of the charge stored in the battery divided by the maximum charge permitted by the battery. The state of charge provides an indirect picture of the energy available in the propulsion battery.

The charge available in the battery is determined from battery state estimators using algorithms based on measurements such as the measurement of the temperature in the vicinity of the cells of the battery, of the individual voltage of the cells and of the current flowing in the battery.

Each cell is fitted with a voltage sensor measuring the voltage across its terminals.

The battery has temperature sensors arranged in the vicinity of the cells used to estimate the temperature of the cells, and is fitted with a current sensor measuring a current flowing through its terminals.

To simplify the production of the battery, the number of temperature sensors is generally lower than the number of cells of the battery.

As the state of charge (SOC) of the battery is a critical piece of data, it is necessary to detect an incorrect SOC value.

It is known to determine two redundant SOC estimates by two independent estimators and compare the SOC estimates produced by the two estimators. To implement both estimators, it may be necessary to redundantly use the sensors and the state of charge estimators to detect an incorrect SOC value by comparing the SOC estimates produced by the estimators.

In addition, it is necessary to implement estimators with a different technology to mitigate common mode failures.

However, the implementation in an aircraft of redundant sensors with different technology on each cell of the batteries and the integration of charge estimators with different technology result in a duplication of the voltage, temperature and current measurement sensors, electronic boards, calculation components and estimator algorithms, and communication buses linking the measurement means to the estimators, making it more complex to create communication harnesses linking said components, and to install the harnesses, the measurement sensors in the battery and the estimators in the aircraft.

The document entitled “State-of-the-art of battery state-of-charge determination” published in December 2005 in the journal “Measurement Science and Technology” and document US 2022/024438 disclose a state of charge estimator for a battery using a Kalman filter

Document US 2022/024438 uses a Kalman filter comprising a battery pack model based on measurements of the temperature, current and voltage of the battery pack.

Document US 2022/024438 also discloses measuring the state of charge of a battery pack based on temperature, current and voltage sensors for the battery pack, and Coulomb Counting.

Document US 2015/0198671 discloses a system for monitoring and balancing battery cells. The system estimates the state of charge of a cell based on variations in the voltage across the terminals of the cell when the cell is being charged or discharged. It also discloses the use of a voltage sum to perform a consistency test of individual voltage measurements.

However, the monitoring system does not provide two redundant SOC estimates.

### DISCLOSURE OF THE INVENTION

The invention aims to overcome all or part of these drawbacks.

The object of the invention is a method for estimating two states of charge of a battery comprising a plurality of cells connected to one another, the method including determining a first state of charge of the battery from the voltage across the terminals of each cell and at least one temperature in the vicinity of each cell, and a current flowing through the terminals of the plurality of cells, and predetermined parametric tables, each parametric table linking a state of charge of a cell to the voltage across the terminals of said cell, to the temperature in the vicinity of said cell, and to the current at the terminals of the plurality of cells.

The method comprises determining a second state of charge of the battery from at least one variable across the terminals of at least one set of cells of the battery, at least one fraction of the plurality of cells forming the set of cells comprising at least two cells.

The two estimates of the state of charge of the battery made from measurements taken on each cell, in the vicinity of each cell and on a set of cells produce two estimates of the state of charge by two different measurement channels without redundantly using the set of sensors and acquisition and processing chains used by the two measurement channels making it possible to simplify the production of the battery and harnesses linking the sensors to means for determining charge states.

The battery preferably has the set of cells forming a pack, determining the second state of charge includes
determining a first variable comprising the voltage across the terminals of each pack and a second variable comprising the current at the terminals of said pack,
determining the temperature of said pack, and
determining the second state of charge of the battery from the voltage across and the current at the terminals of each pack, the temperature of each pack, and a predetermined parametric table linking a state of charge of each pack to the voltage across and the current at the terminals of each pack, and to the temperature of each pack.

The battery advantageously has at least two sets of cells, each set forming a module, determining the second state of charge includes:
determining for each module a first variable comprising the voltage across the terminals of said module and a second variable comprising the current at the terminals of said module,
determining the temperature of each module, and
determining the second state of charge of the battery from the voltage across and the current at the terminals of each module, the temperature of each module, and at least one predetermined parametric table linking a state of charge of each module to the voltage across and the current at the terminals of said module, and to the temperature of said module.

The battery preferably has the set of cells forming a pack, each pack comprising a fraction of the plurality of cells, determining the second state of charge includes:
determining the variable comprising the current at the terminals of each pack,
determining the instantaneous quantity of electricity passing through the terminals of each pack from the current at the terminals of said pack, and
determining the second state of charge from the capacity of each pack and the instantaneous quantity of electricity passing through the terminals of each pack.
   The set of cells of the battery advantageously comprises the plurality of cells of the battery, determining the second state of charge includes:
determining a first variable comprising the voltage across the terminals of the battery and a second variable comprising the current of the battery
determining the temperature of the battery, and
determining the second state of charge from the voltage across and the current at the terminals of the battery, the temperature of the battery, and a predetermined chart linking the second state of charge to the voltage across and the current at the terminals of the battery, and to the temperature of the battery.
   The method also preferably includes comparing the first state of charge and the second state of charge, and wherein:
if the difference in absolute value between the first state of charge and the second state of charge is less than a predetermined threshold, the method includes issuing a signal indicative of the first state of charge,
if the difference in absolute value between the first state of charge and the second state of charge is greater than a predetermined threshold, the method includes issuing a warning signal.

Comparing the two states of charge determined by two different measurement channels makes it possible to detect and warn of the failure of one of the measurement channels.

A device is also proposed for estimating two states of charge of a battery comprising a plurality of cells connected to one another, at least a fraction of the plurality of cells forming at least one set of cells comprising at least two cells, the device comprising:
first determination means comprising predetermined parametric tables and configured to determine a first state of charge of the battery from the voltage across the terminals of each cell and the temperature in the vicinity of each cell, the current flowing through the terminals of the plurality of cells, and parametric tables, each parametric table linking a state of charge of a cell to the voltage across the terminals of said cell, to the temperature of said cell, and to the current at the terminals of the plurality of cells.

The device also comprises:
second determination means configured to determine a second state of charge of the battery from at least one variable measured across the terminals of the set of cells.
   The device also preferably comprises means for comparing the first state of charge and the second state of charge configured to:
issue a signal indicative of the first state of charge if the difference in absolute value between the first state of charge and the second state of charge is less than a predetermined threshold; and
issue a warning signal if the difference in absolute value between the first state of charge and the second state of charge is greater than a predetermined threshold.

A power supply system for an aircraft is also proposed, comprising a battery including a plurality of cells connected to one another, each cell comprising a voltage sensor measuring the voltage across the terminals of said cell, the battery also comprising at least one temperature sensor measuring the temperature in the vicinity of the cells, and a current sensor measuring a current flowing through the terminals of the plurality of cells, the system also comprising measurement means to determine a variable at the terminals of the set of cells, and a device as defined above connected to the voltage, temperature and current sensors and the measurement means.

An aircraft comprising a power supply system as defined above is also proposed.

### BRIEF DESCRIPTION OF THE DRAWINGS

Other aims, features and advantages of the invention will become apparent upon reading the following description, provided purely as a non-limiting example, and with reference to the appended drawings wherein:

FIG. 1 schematically shows an aircraft according to the invention;

FIG. 2 schematically shows a first exemplary power supply system according to the invention;

FIG. 3 schematically shows a second exemplary power supply system according to the invention;

FIG. 4 schematically shows a third exemplary power supply system according to the invention; and

FIG. 5 schematically shows a fourth exemplary power supply system according to the invention.

### DETAILED DISCLOSURE OF AT LEAST ONE EMBODIMENT

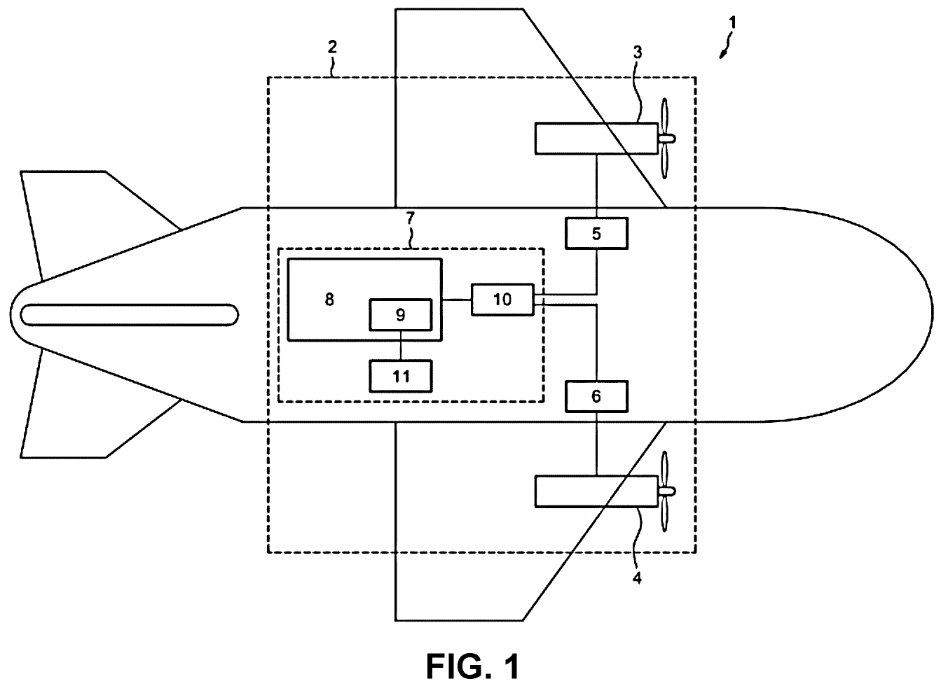

Reference is made to FIG. 1 which schematically shows an aircraft 1 comprising a propulsion system 2.

The propulsion system 2 comprises two rotating electric machines 3, 4 each arranged on either side of a longitudinal axis of the aircraft 1 and each provided with a propeller for propelling the aircraft 1.

Alternatively, the aircraft 1 may comprise more than two rotating electric machines 3, 4 arranged in equal number on either side of the longitudinal axis of the aircraft 1 or a single electric machine arranged on the longitudinal axis of the aircraft 1.

According to another alternative embodiment, the aircraft 1 may comprise a single rotating electric machine.

According to another alternative embodiment, the aircraft 1 is of the hybrid type and comprises at least one rotating electric machine and at least one turboprop engine or a turbojet engine comprising a turbine engine.

The propulsion system 2 also comprises two identical electrical power conversion devices 5, 6, each supplying one of the rotating electric machines 3, 4, and a power supply system 7 supplying the conversion devices 5, 6.

Each conversion device 5, 6 comprises at least one power converter supplying a different rotating electric machine 3, 4.

The power supply system 7 comprises a propulsion battery 8 supplying the conversion devices 5, 6, a device 9 for redundant estimation of two states of charge of the battery 8 connected to the battery 8, and an electrical energy distribution device 10 connected to the battery 8 and to the conversion devices 5, 6.

The battery 8 supplies the rotating electric machines 3, 4 operating in motor mode via the conversion devices 5, 6 and the distribution device 10.

Alternatively, the rotating electric machines 3, 4 operate in generator mode and charge the battery 8 via the conversion devices 5, 6 and the distribution device 10.

The estimation device 9 is integrated in the battery 8.

Alternatively, the estimation device 9 is located outside the battery 8.

Alternatively, the power supply system 7 comprises at least two propulsion batteries, each battery being connected to an estimation device 9.

The estimation device 9 determines two states of charge of the battery 8.

The estimation device 9 is also connected to a data bus 11 of the aircraft 1.

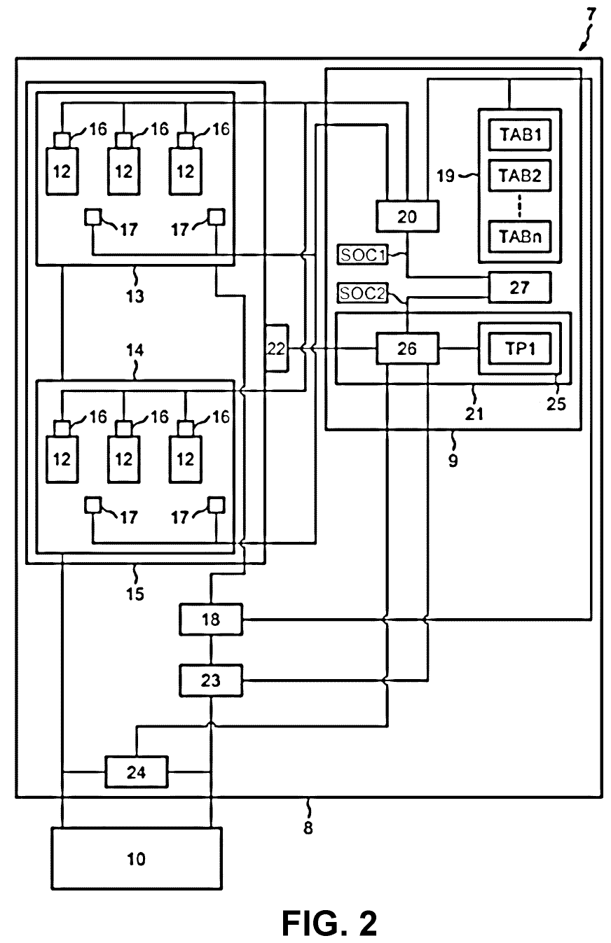

FIG. 2 schematically shows a first exemplary power supply system 7.

The battery 8 comprises a plurality of cells 12 storing electrical energy.

The cells 12 are connected to one another to form two modules 13, 14.

The modules 13, 14 are connected to one another to form a pack 15 connected to the distribution device 10.

The cells 12 are connected to one another in series or in parallel, and the modules 13, 14 are connected to one another in series or in parallel. It is assumed that the modules 13, 14 are connected in series.

Each module 13, 14 comprises the same number of cells 12 and at least one temperature sensor 17 measuring the temperature in the vicinity of the cells 12 such that the temperature measured is indicative of the temperature of the cells 12.

Each module 13, 14 may comprise a plurality of temperature sensors 17 divided between the cells 12 such that the number of sensors 17 is less than the number of cells 12.

Two temperature sensors are, for example, separated by at least two cells 12 as shown in FIG. 2, each module 13, 14 comprising two temperature sensors 17.

Alternatively, two temperature sensors are separated by more than two cells 12, for example by ten cells.

When each module 13, 14 comprises a plurality of sensors 17, the temperature in the vicinity of a cell 12 is, for example, equal to the average of the temperatures measured by the sensors 17 adjacent to said cell 12 or is, for example, equal to the temperature measured by the adjacent sensor 17 closest to said cell 12 out of all the sensors 17.

It is assumed hereinafter that the temperature in the vicinity of a cell 12 is equal to the temperature measured by the adjacent sensor 17 closest to said cell 12 out of all the sensors 17.

Of course, the battery 8 may comprise more than one pack 15, and each pack 15 may comprise more than two modules 13, 14.

Each cell 12 comprises a voltage sensor 16 measuring the voltage across its terminals.

A first current sensor 18 measures the current flowing through the terminals of the battery 8.

The estimation device 9 comprises first storage means 19, for example a non-volatile memory, storing predetermined parametric tables TAB1, TAB2. . . . TABn, n being an integer equal to the number of cells 12.

Each parametric table is associated with a different cell 12 and links a state of charge of a cell 12 to the voltage across the terminals of said cell 12, to the temperature in the vicinity of said cell 12, and to the current at the terminals of the pack 15.

The parametric tables are determined, for example, on the basis of an equivalent electrical circuit for the cell 12, enabling the transfer function between the current and voltage of the cell 12 to be calculated for a given state of charge and temperature.

The equivalent circuit is, for example, of the resistive or resistive and capacitive type.

According to one variant, the cells 12 are identical such that the parametric tables are identical.

In addition, the first determination means 20 determine a first state of charge SOC1 of the battery 8 from the voltage across the terminals of each cell 12 measured by the voltage sensor 16 associated with said cell 12, from the temperature in the vicinity of each cell 12 measured by the temperature sensors 17 associated with said cell 12, from the current flowing through the terminals of the pack 15 measured by the current sensor 18, and from the predetermined parametric tables TAB1, . . . . TABn.

The first determination means 20 determine an intermediate state of charge of each cell 12 by identifying the value of the intermediate state of charge of each cell 12 associated by the parametric table TABn of said cell 12 with the voltage value and temperature value in the vicinity of said cell 12, and with the measured current value.

The first determination means 20 are produced, for example, from a first processing unit and comprise the storage means 19.

The first determination means 20 determine the intermediate state of charge for each cell 12 and deduce the first state of charge SOC1, for example, by averaging all of the intermediate states of charge or by retaining the greatest value of the intermediate state of charge, or by retaining the smallest value of the intermediate state of charge.

The greatest value of the intermediate state of charge is retained, for example, when the battery 8 is being charged to define when the charging stops. When the greatest value of the intermediate state of charge reaches a maximum charging value, the battery 8 charging is stopped so as to prevent the cell or cells 12 which have reached the maximum charging value from deteriorating. The battery 8 is considered to be fully charged.

The smallest value of the intermediate state of charge is retained, for example, to determine when the battery 8 is discharged.

When the smallest value of the intermediate state of charge reaches a maximum discharge value, the battery 8 charge is considered to be fully discharged.

The sensors 16, 17, 18, first storage means 19, and the first determination means 20 form a first measurement channel.

The estimation device 9 also comprises measurement means to determine at least one variable at the terminals of at least one set of cells, and second determination means 21 to determine a second state of charge SOC2 of the battery 8 from the variable measured by the measurement means.

The set of cells has at least one fraction of the plurality of cells 12, the number of cells 12 integrated in the set of cells ranging from two cells 12 to the plurality of cells 12 of the battery 8.

The second determination means 21 and the measurement means form a second measurement channel.

In this example, the set of cells has the plurality of cells 12 forming the pack 15 of the battery 8, and the measurement means comprise a second temperature sensor 22 measuring the temperature of the pack 15, a second current sensor 23 measuring the current flowing through the terminals of the pack 15, and a second voltage sensor 24 measuring the voltage across the terminals of the pack 15.

The second determination means 21 comprise second storage means 25 comprising, for example, a non-volatile memory and storing a predetermined parametric table TP1 linking a state of charge of the pack 15 to the voltage measured by the second voltage sensor 24, to the current measured by the second current sensor 23 of each pack, and to the temperature measured by the second temperature sensor 22.

As the battery 8 comprises a single pack 15, the second stage of charge SOC2 of the battery 8 is equal to the state of charge of the pack 15.

The parametric table TP1 is, for example, determined on the basis of an equivalent electrical circuit for the pack 15, enabling the transfer function between the current and voltage of the pack 15 to be calculated for a given state of charge and temperature.

The equivalent circuit is, for example, of the resistive or resistive and capacitive type.

The second determination means 21 also comprise means 26 for operating the second storage means 25.

The operating means 26 determine the value of the second state of charge SOC2 of the battery 8 by identifying the value of the state of charge associated by the parametric table TP1 with the voltage and temperature values measured by the second sensors 22, 24 and with the value of the current measured by the second current sensor 23.

The operating means 26 comprise, for example, a second processing unit.

If the battery 8 comprises a plurality of packs, each pack comprises a second temperature sensor, a second current sensor if the packs are connected in parallel in order to measure the current flowing through said pack, and a second voltage sensor, the second determination means 21 determining an intermediate state of charge for each pack and adding up the intermediate states of charge of the packs to determine the second state of charge SOC2 of the battery 8.

The first and second estimation means, the voltage sensors 16 and the second voltage sensor 24, the current sensor 18 and the second current sensor 23, and the temperature sensors 17 and the second temperature sensor 22 have different technologies to mitigate common mode failures.

The estimation device 9 also comprises means 27 for comparing the first state of charge SOC1 and the second state of charge SOC2 issuing a signal indicative of the first state of charge SOC1 if the difference in absolute value between the first state of charge SOC1 and the second state of charge SOC2 is less than a predetermined threshold.

The predetermined threshold is determined such that the difference between the values of the first state of charge SOC1 and the second state of charge SOC2 is within an acceptable uncertainty range determined from the measurement uncertainty of the sensors, the dispersion of the cells 12, the temperature, and the precision of the signal acquisition and processing chain.

The indicative signal is transmitted by the comparison means 27 to the bus 11 such that the value of the first state of charge SOC1 is used by other bodies of the aircraft 1, for example by a display located in the cockpit of the aircraft 1 to visually indicate the state of charge of the battery 8 to the pilots.

The comparison means 27 comprise, for example, a third processing unit.

If the difference in absolute value between the first state of charge and the second state of charge is greater than a predetermined threshold, one of the determination means 20, 21 is considered to be faulty. The comparison means 27 issue a warning signal to the bus 11.

The measures taken after the warning signal has been received depend, for example, on the design of the aircraft 1 and the operational safety strategy adopted.

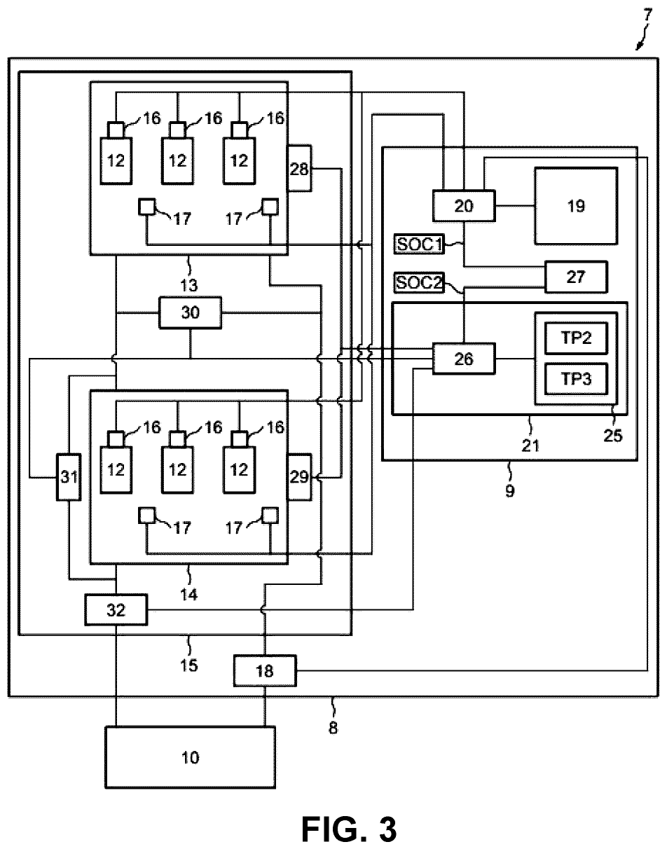

FIG. 3 schematically shows a second exemplary power supply system 7.

There is the battery 8 comprising the pack 15, and the estimation device 9 comprising the first estimation means 20, the first storage means 19, and the comparison means 27.

This example differs from the previous example shown in FIG. 2 in that the battery 8 comprises two sets of cells, each set of cells being formed by a different module 13, 14, and the measurement means comprise, for each set of cells formed by a module 13, 14, a third temperature sensor 28, 29 measuring the temperature of said module 13, 14, a third voltage sensor 30, 31 measuring the voltage across the terminals of each set of cells, and a third current sensor 30 measuring the current flowing through the terminals of each set of cells.

As the modules 13, 14 are connected in series, the current flowing through the terminals of the modules 13, 14 is identical, a single third sensor 32 measures the current at the terminals of the second module 14. In addition, the second determination means 21 differ from the second determination means 21 shown in FIG. 2 in that the second storage means 25 store for each module 14, a predetermined parametric table TP2, TP3 linking a state of charge of each module 13, 14, to the voltage and current measured at the terminals of said module 13, 14, and to the temperature of said module 13,14.

Each parametric table TP2, TP3 is, for example, determined on the basis of an equivalent electrical circuit for each module 13, 14 enabling the transfer function between the current and voltage of each module 13, 14 to be calculated for a given state of charge and temperature.

The equivalent circuit is, for example, of the resistive or resistive and capacitive type.

The operating means 26 determine the state of charge of each module 13, 14 by identifying the value of the state of charge of each module 13, 14 associated by the parametric table TP2, TP3 with the voltage and temperature values measured by the third sensors 28, 30 and 29, 32, and with the current value measured by the third current sensor 32.

The operating means 26 determine the value of the second state of charge SOC2 by adding up the states of charge of the modules 13, 14.

The first and second estimation means 20, 21, the voltage sensors 16 and the third voltage sensors 30, 31, the current sensor 18 and the third current sensor 32, and the temperature sensors 17 and the third temperature sensors 28, 29 have different technology to mitigate common mode failures.

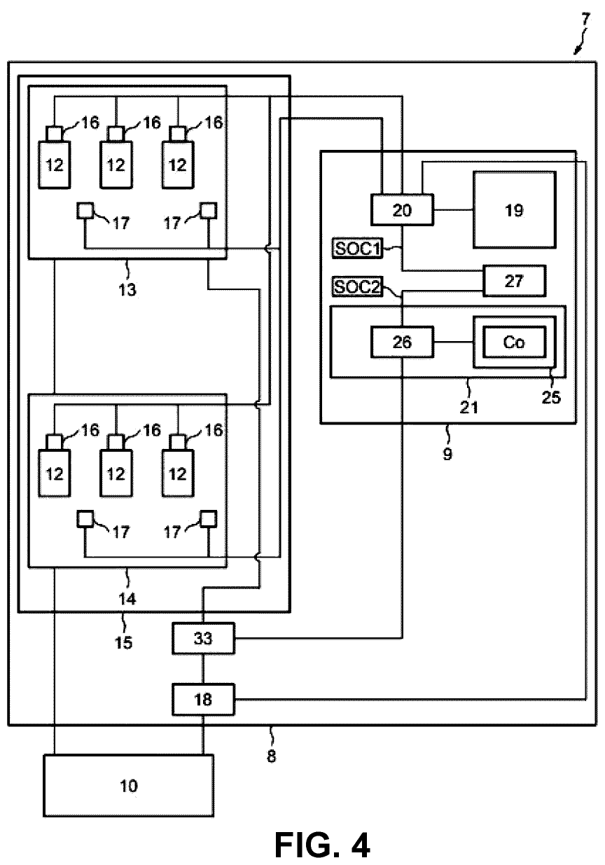

FIG. 4 schematically shows a third exemplary power supply system 7.

There is the battery 8 comprising the pack 15, and the estimation device 9 comprising the first estimation means 20, the first storage means 19, and the comparison means 27.

This example differs from the previous example shown in FIG. 2 in that the measurement means comprise a fourth current sensor 33 measuring the current at the terminals of the pack 15 forming the set of cells.

In addition, the second determination means 21 differ from the second determination means 21 shown in FIG. 2 in that the second storage means 25 store the value of the total capacity Co of the pack 15, and the operating means 26 determine the value of the second state of charge SOC2 by determining the instantaneous quantity of electricity passing through the terminals of the pack 15 from measurements from the fourth current sensor 33 adding or subtracting said quantity of electricity from the total capacity Co depending on whether the pack 15 is supplying or receiving electrical energy. The operating means comprise, for example, a shunt or Hall effect current sensor.

The first and second estimation means 20, 21, the current sensor 18 and the fourth current sensor 33 have different technologies to mitigate common mode failures.

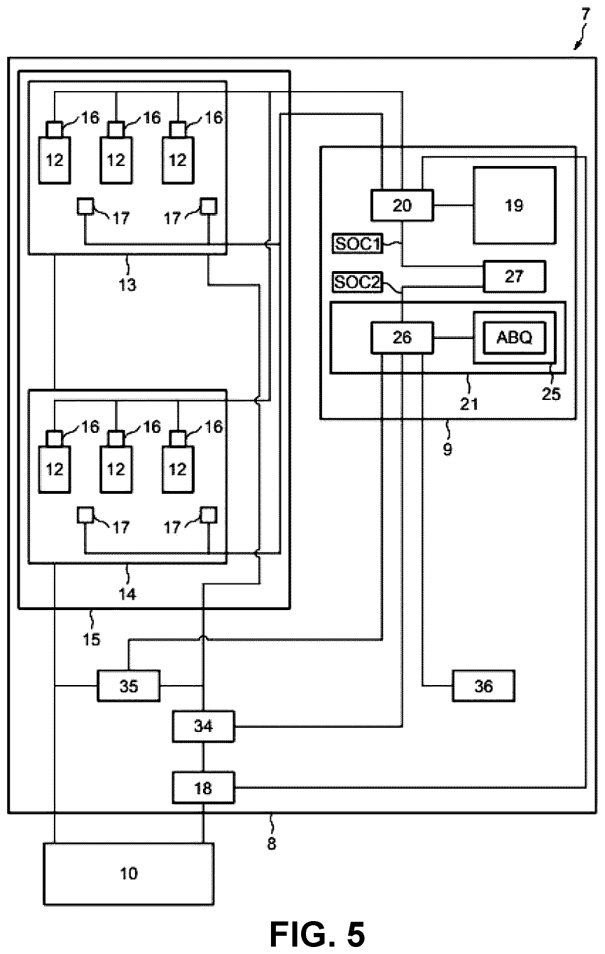

FIG. 5 schematically shows a fourth exemplary power supply system 7.

There is the battery 8 comprising the pack 15, and the estimation device 9 comprising the first estimation means 20, the first storage means 19, and the comparison means 27.

This example differs from the previous example shown in FIG. 2 in that the measurement means comprise a fifth current sensor 34 measuring the current at the terminals of the battery 8, a fifth voltage sensor 35 measuring the voltage across the terminals of the battery 8, and a fifth temperature sensor 36 measuring the temperature of the battery 8.

All the cells 12 in the battery 8 form the set of cells.

In addition, the second determination means 21 differ from the second determination means 21 shown in FIG. 2 in that the second storage means 25 store a predetermined chart ABQ linking the second state of charge SOC2 to the voltage and to the current flowing through the terminals of the battery 8 measured by the fifth sensors 34, 35, and to the temperature measured by the fifth temperature sensor 36.

The operating means 26 determine the second state of charge SOC2 by identifying the value of the second state of charge SOC2 associated by the chart ABQ with the voltage and temperature values measured by the fifth sensors 36, 35 and with the value of the current measured by the fifth current sensor 34.

The first and second estimation means 20, 21, the voltage sensors 16 and the fifth voltage sensor 35, the current sensor 18 and the fifth current sensor 34, and the temperature sensors 17 and the fifth temperature sensors 36 have different technology to mitigate common mode failures.

The fact that the estimation device 9 has two different measurement channels makes it possible to obtain two estimates of the state of charge without redundantly using all the sensors implemented by the two measurement channels, simplifying the production of the battery and harnesses connecting the sensors to the means for determining the states of charge of the measurement channels.

These simplifications reduce the size and weight of system 7.

In addition, installing sensors 16, 17, 18 and first determination means 20 in the first channel and sensors 22, 23, 24, 28, 29, 30, 31, 32, 33, 34, 35, 36 in the second measurement channel with a different technology from that of the first measurement channel, and second determination means 21 in the second measurement channel with a different technology from that of the first measurement channel improves the operational reliability of the system 7.

The estimates of the state of charge SOC1, SOC2 of the battery 8 and the comparison of the states of charge with one another make it possible to detect and warn of the failure of one of the means 20, 21 for determining the state of charge of the battery 8.

1. A method for estimating two states of charge (SOC1, SOC2) of a battery having a plurality of cells connected to one another, the method comprising:
determining a first state of charge (SOC1) of the battery from a voltage across terminals of each cell and at least one temperature in the vicinity of each cell, and a current flowing through the terminals of the plurality of cells, and predetermined parametric tables (TAB1, TAB2, TABn), each parametric table linking a state of charge of a cell to the voltage across the terminals of said cell, to the temperature in the vicinity of said cell, and to the current at the terminals of the plurality of cells; and
determining a second state of charge (SOC2) of the battery from at least one variable measured across the terminals of at least one set of cells of the battery, at least one fraction of the plurality of cells forming the set of cells comprising at least two cells.

2. The method according to claim 1, the battery comprising the set of cells forming a pack, wherein the step of determining the second state of charge further includes:
determining a first variable comprising the voltage across the terminals of each pack and a second variable comprising the current at the terminals of said pack,
determining the temperature of said pack, and
determining the second state of charge (SOC2) of the battery from the voltage across and the current at the terminals of each pack, the temperature of each pack, and a predetermined parametric table (TP1) linking a state of charge of each pack to the voltage across and the current at the terminals of each pack, and to the temperature of each pack.

3. The method according to claim 1, the battery comprising at least two sets of cells, each set forming a module, wherein the step of determining the second state of charge further includes:
determining for each module a first variable comprising the voltage across the terminals of said module and a second variable comprising the current at the terminals of said module,
determining the temperature of each module, and
determining the second state of charge of the battery from the voltage across and the current at the terminals of each module, the temperature of each module, and at least one predetermined parametric table (TP2, TP3) linking a state of charge of each module to the voltage across and the current at the terminals of said module, and to the temperature of said module.

4. The method according to claim 1, the battery comprising the set of cells forming a pack, each pack comprising a fraction of the plurality of cells, wherein the step of determining the second state of charge further includes:
determining the variable comprising the current at the terminals of each pack,
determining an instantaneous quantity of electricity passing through the terminals of each pack from the current at the terminals of said pack, and
determining the second state of charge from a capacity of each pack (Co) and the instantaneous quantity of electricity passing through the terminals of each pack.

5. The method according to claim 1, wherein the set of cells of the battery has the plurality of cells of the battery, and the step of determining the second state of charge further includes:
determining a first variable comprising the voltage across the terminals of the battery and a second variable comprising the current of the battery
determining the temperature of the battery, and
determining the second state of charge from the voltage across and the current at the terminals of the battery, the temperature of the battery, and a predetermined chart (ABQ) linking the second state of charge to the voltage across and the current at the terminals of the battery, and to the temperature of the battery.

6. The method according to claim 1, further including the step of comparing the first state of charge (SOC1) and the second state of charge (SOC2), wherein:
if a difference in absolute value between the first state of charge and the second state of charge is less than a predetermined threshold, the method further includes issuing a signal indicative of the first state of charge, and
if the difference in absolute value between the first state of charge and the second state of charge is greater than a predetermined threshold, the method includes issuing a warning signal.

7. A device for estimating two states of charge (SOC1, SOC2) of a battery comprising a plurality of cells connected to one another, at least one fraction of the plurality of cells forming at least one set of cells comprising at least two cells, the device comprising:
first determination means comprising predetermined parametric tables (TAB1, TAB2, TABn) and being configured to determine a first state of charge (SOC1) of the battery from a voltage across terminals of each cell and a temperature in a vicinity of each cell, a current flowing through the terminals of the plurality of cells, and parametric tables, each parametric table linking a state of charge of a cell to the voltage across the terminals of said cell, to the temperature in the vicinity of said cell, and to the current at the terminals of the plurality of cells, and
second determination means configured to determine a second state of charge (SOC2) of the battery from at least one variable measured across the terminals of the set of cells.

8. The device according to claim 7, further comprising means for comparing the first state of charge (SOC1) and the second state of charge (SOC2) and configured to:
issue a signal indicative of the first state of charge if a difference in absolute value between the first state of charge and the second state of charge is less than a predetermined threshold; and
issue a warning signal if the difference in absolute value between the first state of charge and the second state of charge is greater than a predetermined threshold.

9. A power supply system for an aircraft, comprising a battery having a plurality of cells connected to one another, each cell comprising a voltage sensor measuring a voltage across terminals of said cell, the battery further comprising at least one temperature sensor measuring a temperature in a vicinity of the cells, and a current sensor measuring a current flowing through the terminals of the plurality of cells, the system further comprising measurement means configured to determine a variable at the terminals of the set of cells, and the device according to claim 7 connected to the voltage, temperature and current sensors, and the measurement means.

10. An aircraft comprising the power supply system according to claim 9.
